(19) United States
(12) Patent Application Publication
(10) Pub. No.: US 2024/0038900 A1
(43) Pub. Date: Feb. 1, 2024

(54) THIN-FILM TRANSISTOR HAVING VERTICAL STRUCTURE AND ELECTRONIC DEVICE

(71) Applicant: WUHAN CHINA STAR OPTOELECTRONICS TECHNOLOGY CO., LTD., Wuhan (CN)

(72) Inventors: Zhifu Li, Wuhan (CN); Guanghui Liu, Wuhan (CN); Fei Ai, Wuhan (CN); Dewei Song, Wuhan (CN); Chengzhi Luo, Wuhan (CN)

(73) Assignee: WUHAN CHINA STAR OPTOELECTRONICS TECHNOLOGY CO., LTD., Wuhan (CN)

(21) Appl. No.: 18/050,753

(22) Filed: Oct. 28, 2022

(30) Foreign Application Priority Data
Jul. 27, 2022 (CN) 202210895874.2

(51) Int. Cl. H01L 29/786; H01L 29/66

(52) U.S. Cl. CPC H01L 29/78696; H01L 29/66757; H01L 29/78633; H01L 29/78675

(57) ABSTRACT

A thin-film transistor (TFT) having a vertical structure and an electronic device are provided. The TFT having the vertical structure includes an insulating substrate and an active layer disposed on the insulating substrate. The active layer includes a first conductive part, an active section, and a second conductive part which are stacked. An orthographic projection of the first conductive part on the insulating substrate partly overlaps an orthographic projection of the second conductive part on the insulating substrate. Therefore, contamination ions may be prevented from entering the active section from the insulating substrate during manufacturing processes of the TFT. Thus, reliability of performance of the TFT may be improved.

### FIELD

The present disclosure relates to a field of display technologies, and more particularly, to a thin-film transistor having a vertical structure and an electronic device.

### BACKGROUND

Flat display devices, e.g., liquid crystal displays (LCD) mobile terminals and organic light-emitting diodes (OLED) mobile terminals, have advantages of high image quality, low electric power consumption, a thin and light body, and wide application fields. Therefore, they are widely used in many consumer electronics, such as cell phones, televisions, personal digital assistances, digital cameras, laptops, and desktops, and become a mainstream display device currently.

In conventional technologies, it is known that integrating pixel integrated circuits (ICs), driving ICs, multiplexer ICs, control ICs, and logic ICs into a glass substrate, which is called system on glass (SOC), may increase an integration degree of semiconductor devices and reduce dependence on IC chips. To realize the SOC, an integration degree, a maximum working frequency, and a current density of conventional thin-film transistors (TFTs) need to be increased. Electrical performance of the TFTs is relevant to a part of the active layer between a source and a drain, i.e., a length of a channel of the active layer. Therefore, to achieve the above effects, the length of the channel and a size of the TFTs need to be reduced. However, in conventional manufacturing processes of the TFTs, a minimum size of a pattern of an I-type active layer manufactured by conventional apparatuses is generally greater than 2 μm. As such, a short channel of the TFTs is difficult to be realized in conventional technologies. Furthermore, when a length of a channel of devices is reduced, a distance between a source and a drain of the devices is also reduced, resulting in a poor capability of a gate to control the channel. Thus, a subthreshold leakage phenomenon, i.e., short-channel effects, is more likely to occur.

### SUMMARY

Embodiments of the present disclosure provide a display panel and a mobile terminal to alleviate insufficiencies of relevant technologies.

To achieve the above goals, technical solutions provided by the embodiments of the present disclosure are described as follows.

An embodiment of the present disclosure provides a thin-film transistor (TFT) having a vertical structure, comprising:
an insulating substrate;
an active layer disposed on the insulating substrate, wherein the active layer comprises a first conductive part, an active section, and a second conductive part which are stacked;
wherein an orthographic projection of the first conductive part on the insulating substrate partly overlaps an orthographic projection of the second conductive part on the insulating substrate.

In the TFT having the vertical structure provided by the embodiments of the present disclosure, a thickness of the second conductive part is greater than a thickness of the first conductive part.

In the TFT having the vertical structure provided by the embodiments of the present disclosure, the thickness of the second conductive part is two times greater than the thickness of the first conductive part.

In the TFT having the vertical structure provided by the embodiments of the present disclosure, in a direction perpendicular to the insulating substrate, the thickness of the second conductive part is greater than or equal to 50 nm and is less than or equal to 300 um, and the thickness of the first conductive part is greater than or equal to 10 nm and is less than or equal to 100 p.m.

In the TFT having the vertical structure provided by the embodiments of the present disclosure, the active layer comprises a first active layer, a second active layer, and a third active layer which are stacked and disposed on the insulating substrate;
wherein the active layer comprises the first conductive part doped with an ion, and the third active layer comprises the second conductive part doped with an ion.

In the TFT having the vertical structure provided by the embodiments of the present disclosure, the active layer section and the second conductive part have a same shape.

In the TFT having the vertical structure provided by the embodiments of the present disclosure, a dopant concentration of the ion of the second conductive part is less than a dopant concentration of the ion of the first conductive part.

In the TFT having the vertical structure provided by the embodiments of the present disclosure, the TFT having the vertical structure comprises a gate disposed on a lateral wall of the active layer, and an orthographic projection of the gate on the lateral wall of the active layer covers the active section.

In the TFT having the vertical structure provided by the embodiments of the present disclosure, the orthographic projection of the gate on the insulating substrate overlaps a side of an orthographic projection of the active section on the insulating substrate.

In the TFT having the vertical structure provided by the embodiments of the present disclosure, the orthographic projection of the gate on the insulating substrate overlaps two sides or multiple sides of an orthographic projection of the active section on the insulating substrate.

In the TFT having the vertical structure provided by the embodiments of the present disclosure, the TFT having the vertical structure comprises:
a light-shielding layer disposed between the insulating substrate and the active layer, wherein an orthographic projection of the light-shielding layer on the insulating substrate at least covers an orthographic projection of the active section on the insulating substrate, and the gate is connected to the light-shielding layer.

In the TFT having the vertical structure provided by the embodiments of the present disclosure, a thickness of the active section is greater than or equal to 0.1 um and is less than or equal to 1 um.

In the TFT having the vertical structure provided by the embodiments of the present disclosure, the TFT having the vertical structure comprises a first metal layer disposed on a side of the active layer away from the insulating substrate, wherein the first metal layer is connected to the first conductive layer;
wherein the first conductive part comprises a first sub-conductive part connected to the active section and a second sub-conductive part connected to the first metal layer, an orthographic projection of the first sub-conductive part on the insulating substrate overlaps an orthographic projection of the second conductive part on the insulating substrate, and an orthographic projection of the second sub-conductive part on the insulating substrate does not overlap the orthographic projection of the second sub-conductive part on the insulating substrate.

An embodiment of the present disclosure provides an electronic device, comprising any one of the above the TFTs having the vertical structure.

Regarding the beneficial effects: embodiments of the present disclosure provide a TFT having a vertical structure and an electronic device. The TFT having the vertical structure comprises an insulating substrate and an active layer disposed on the insulating substrate. The active layer comprises a first conductive part, an active section, and a second conductive part which are stacked. In the embodiments of the present disclosure, an orthographic projection of the first conductive part on the insulating substrate partly overlaps an orthographic projection of the second conductive part on the insulating substrate. Therefore, contamination ions may be prevented from entering the active section from the insulating substrate during conventional manufacturing processes of TFTs. Thus, reliability of performance of the TFTs may be improved. Furthermore, because the first conductive part, the active section, and the second conductive part are stacked along a direction perpendicular to the insulating substrate, a length of a channel is reduced. As such, short-channel effects are reduced, an on-state current is increased, and power consumption is reduced. Thus, an area occupied by the TFT having the vertical structure is further reduced, an aperture ratio is increased, and an integration degree of the TFT having the vertical structure is increased, which are beneficial for developing products having high pixels per inch (PPI) and high refresh rate and realizing some IC functions.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which those skilled in the art can derive further figures without making any inventive efforts.

FIG. 1 is a top view showing a cross-section of a conventional thin-film transistor (TFT).

FIG. 2 is a structural schematic view showing a cross-section taken along a direction A-A′ in FIG. 1.

FIG. 3 is a structural schematic view showing a cross-section along a direction B-B′ in FIG. 1.

FIG. 4 is a first schematic top view showing a TFT having a vertical structure provided by an embodiment of the present disclosure.

FIG. 5 is a structural schematic view showing a cross-section taken along a direction A-A′ in FIG. 4.

FIG. 6 is a structural schematic view showing a cross-section taken along a direction B-B′ in FIG. 4.

FIG. 7 is a second schematic top view showing a TFT having a vertical structure provided by an embodiment of the present disclosure.

FIG. 8 is a structural schematic view showing a cross-section taken along a direction B-B′ in FIG. 7.

FIG. 9 is a third schematic top view showing a TFT having a vertical structure provided by an embodiment of the present disclosure.

FIG. 10 is a structural schematic view showing a cross-section taken along a direction B-B′ in FIG. 9.

FIG. 11 is a flowchart showing a manufacturing method of a TFT having a vertical structure provided by an embodiment of the present disclosure.

FIGS. 12A to 12J are manufacturing flowcharts showing structures of the TFT having the vertical structure in FIG. 11.

### DETAILED DESCRIPTION

Hereinafter preferred embodiments of the present disclosure will be described with reference to the accompanying drawings to exemplify the embodiments of the present disclosure can be implemented, which can fully describe the technical contents of the present disclosure to make the technical content of the present disclosure clearer and easy to understand. However, the described embodiments are only some of the embodiments of the present disclosure, but not all of the embodiments. All other embodiments obtained by those skilled in the art based on the embodiments of the present disclosure without creative efforts are within the scope of the present disclosure. It should be noted that described embodiments are merely used to construct the present disclosure and are not intended to limit the present disclosure. In the present disclosure, unless further description is made, terms such as “top” and “bottom” usually refer to a top of a device and a bottom of a device in an actual process or working status, and specifically, to the orientation as shown in the drawings. Terms such as “inside” and “outside” are based on an outline of a device.

Embodiments of the present disclosure provide a TFT having a vertical structure and an electronic device which are respectively described in detail as follows. It should be noted that a description order of following embodiments does not limit a preferred description order of the embodiments.

Please refer to FIGS. 4 to 12J, embodiments of the present disclosure provide a TFT having a vertical structure and an electronic device. A TFT 10 having a vertical structure includes:
an insulating substrate 11;
an active layer 21 disposed on the insulating substrate 11, wherein the active layer 21 includes a first conductive part 21A, an active section 21B, and a second conductive part 21C which are stacked.

An orthographic projection of the first conductive part 21A on the insulating substrate 11 partly overlaps an orthographic projection of the second conductive part 21C on the insulating substrate 11.

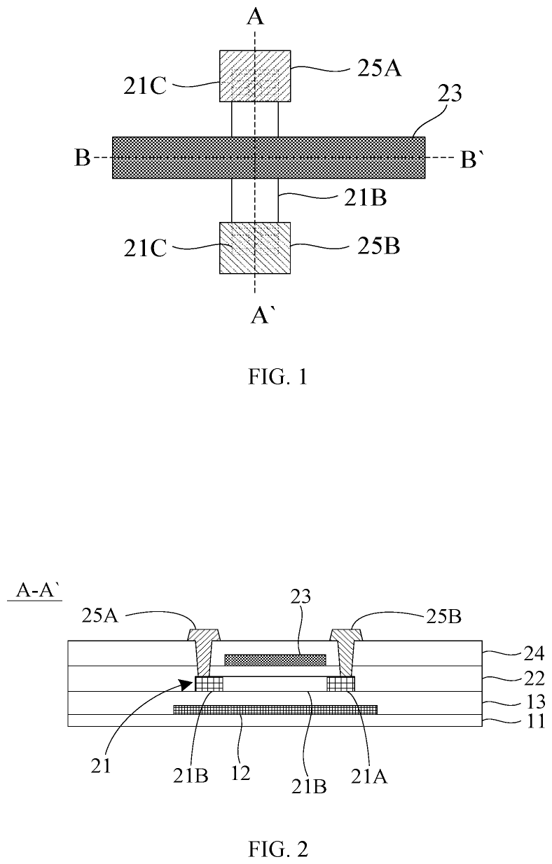

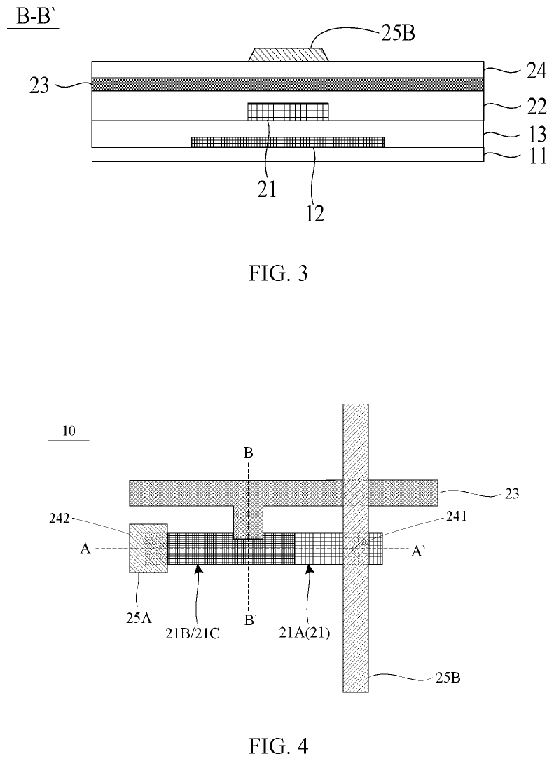

Please refer to FIG. 1, FIG. 2, and FIG. 3. FIG. 1 is a top view showing a cross-section of a conventional TFT. FIG. 2 is a structural schematic view showing a cross-section along a direction A-A′ in FIG. 1. FIG. 3 is a structural schematic view showing a cross-section along a direction B-B′ in FIG. 1.

The conventional TFT includes an insulating substrate 11, a light-shielding layer 12, a buffer layer 13, an active layer 21, an insulating layer 22, a gate 23, an interlayer insulating layer 24, a source 25A, and a drain 25B which are stacked on the insulating substrate 11. It should be noted that types of conventional TFTs are not limited to the present embodiment. In the present embodiment, a conventional display panel including a top-gate TFT is taken as an example for description.

It should be understood that with continuous development of a display panel industry, consumers put forward higher and higher demands for display panels having a narrow frame, a high aperture rate, high brightness, and high resolution. To achieve the above effects, an integration rate, a maximum working frequency, and a current density of conventional TFTs need to be increased. Electrical performance of the TFTs is relevant to a part of the active layer between a source and a drain, i.e., a length of a channel of the active layer. Therefore, to achieve the above effects, the length of the channel and a size of the TFTs need to be reduced. However, in conventional manufacturing processes of the TFTs, a minimum size of a pattern of an I-type active layer manufactured by conventional apparatuses is generally greater than 2 μm. As such, a short channel of the TFTs is difficult to be realized.

In the present embodiment, the active layer 21 includes the first conductive part 21A, the active section 21B, and the second conductive part 21C which are stacked. A channel 210 of the TFT 10 having the vertical structure is disposed between the first conductive part 21A and the second conductive part 21C. That is, in the present embodiment, a length of the channel 210 of the TFT 10 having the vertical structure is determined by a thickness of the active section 21B. Therefore, although the thickness of the active section 21B is limited because of exposure apparatuses, the thickness of the active section 21B may be controlled. As such, the length of the channel 210 may be controlled independently of exposure apparatuses, and a short channel of TFTs can be realized, which increases an on-state current and reduces power consumption. Furthermore, an area occupied by the TFT having the vertical structure is further reduced. Thus, an aperture ratio and an integration degree of the TFT having the vertical structure are increased, which are beneficial for developing products having high pixels per inch (PPI) and high refresh rate and realizing some IC functions. Furthermore, the TFT having the vertical structure provided by the present embodiment has characteristics such as small size and high integration degree. Therefore, functions, such as data storage and voltage switch, of ICs may also be realized.

Moreover, in the present embodiment, the orthographic projection of the first conductive part 21A on the insulating substrate 11 partly overlaps the orthographic projection of the second conductive part 21C on the insulating substrate 11. As such, contamination ions may be prevented from entering the active section 21B from the insulating substrate 11 during conventional manufacturing processes of TFTs. Thus, reliability of performance of the TFTs may be improved.

Technical solutions provided by the present disclosure are described below in conjunction with specific embodiments.

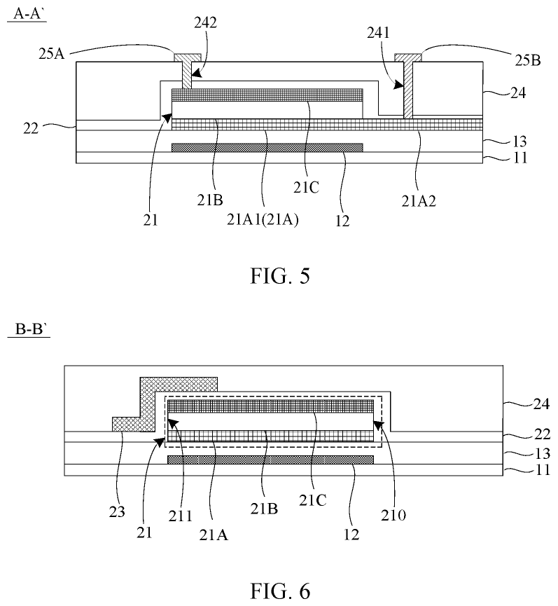

Please refer to FIG. 4, FIG. 5, and FIG. 6. FIG. 4 is a first schematic top view showing a TFT having a vertical structure provided by an embodiment of the present disclosure.

FIG. 5 is a structural schematic view showing a cross-section taken along a direction A-A′ in FIG. 4. FIG. 6 is a structural schematic view showing a cross-section taken along a direction B-B′ in FIG. 4.

The present embodiment provides a TFT 10 having a vertical structure. The TFT 10 having the vertical structure includes a first conductive part 21A, an active section 21B, and a second conductive part 21C. A channel 210 of the TFT 10 having the vertical structure is disposed between the first conductive part 21A and the second conductive part 21C. That is, in the present embodiment, a length of the channel 210 of the TFT 10 having the vertical structure can be determined by a thickness of the active section 21B. Therefore, although the thickness of the active section 21B is limited because of exposure apparatuses, the thickness of the active section 21B can be controlled. As such, the length of the channel 210 can be controlled independently of the exposure apparatuses, thereby realizing a short channel of the TFT.

Preferably, in the present embodiment, the thickness of the active section 21B is greater than or equal to 0.01 μm and is less than or equal to 0.1 μm. Preferably, the thickness of the active section 21B is 0.02 μm, 0.03 μm, or 0.04 μm. It should be understood that, in the present embodiment, the length of the TFT 10 having the vertical structure can be determined by the thickness of the active section 21B. In conventional manufacturing processes of TFTs, a length of a channel 210 is limited because of exposure apparatuses and is commonly greater than 2 μm. In the present embodiment, the active layer 21 includes the first conductive part 21A, the active section 21B, and the second conductive part 21C which are stacked. The thickness of the active section 21B is greater than or equal to 0.01 μm and is less than or equal to 0.1 μm. As such, the length of the channel 210 is reduced, which reduces short-channel effects, increases an on-state current, and reduces power consumption. Furthermore, a size of the TFT is reduced, which is beneficial for manufacturing TFTs having a minor size.

It should be noted that, in the present embodiment, the active layer 21 includes a first active layer, a second active layer, and a third active layer which are stacked on the insulating substrate 11. The active layer 21 includes the conductive part 21A doped with an ion. The third active layer includes the second conductive part 21C doped with an ion. That is, in the present embodiment, the active layer 21 is formed of the first active layer, the second active layer, and the third active layer which are staked. The first conductive part 21A includes a dopant ion, and the second conductive part 21C includes a dopant ion.

Furthermore, in the present embodiment, the active section 21B and the second conductive part 21C have a same shape. An orthographic projection of the first conductive part 21A on the insulating substrate 11 partly overlaps an orthographic projection of the second conductive part 21C on the insulating substrate 11. Specifically, an orthographic projection of the active section 21B on the insulating substrate 11 overlaps an orthographic projection of the second conductive part 21C on the insulating substrate 11. The active section 21B and the second conductive part 21C have a same projection pattern.

It should be understood that, in conventional manufacturing processes of TFTs, contamination ions may diffuse from the insulating substrate toward the active layer 21, destroying stability of the TFTs. In the present embodiment, the active section 21B and the second conductive part 21C have the same shape. The orthographic projection of the first conductive part 21A on the insulating substrate 11 partly overlaps the orthographic projection of the second conductive part 21C on the insulating substrate 11. Therefore, contamination ions can be prevented from entering the active section 21B from the insulating substrate 11 during manufacturing processes of the TFT, thereby improving stability of the TFT.

It should be noted that, in the present embodiment, a thickness of the first conductive part 21A is greater than or equal to 10 nm or less than or equal to 100 nm. Preferably, the thickness of the first conductive part 21A is 35 nm, 45 nm, or 55 nm.

In the present embodiment, material of the active layer 21 includes, but is not limited to, one of polysilicon, amorphous silicon, or oxide semiconductors. Preferably, the material of the active layer 21 includes polysilicon which is taken as an example for description.

Furthermore, in the present embodiment, the first conductive part 21A and the second conductive part 21C both can be polysilicon manufactured from silicide doped with high-concentration n-type impurities. The silicide includes, but is not limited to, amorphous silicon (a-Si). A thickness of the second conductive part 21C is greater than a thickness of the first conductive part 21A. It should be understood that when TFTs are manufactured in conventional technologies, a conductive process is performed on a contact area between the source 25A and the source 25B of the active layer 21 with plasma gas to reduce electrical resistance due to overlapping connection between the source 25A and the drain 25B, thereby improving performance of the TFTs. Plasma gas is easy to diffuse and makes the channel 210 of the active layer 21 conductive, but this results in the channel 210 losing semiconductor properties and leading to a length of the channel 210 of TFTs on a substrate uneven.

It should be understood that using silicide doped with high-concentration n-type impurities to form polysilicon of the first conductive part 21A and the second conductive part 21C is only an example. In another embodiment, the first conductive part 21A and the second conductive part 21C is an a-Si layer doped with high-concentration n-type impurities. Therefore, it is not necessary to additionally inject ions during manufacturing processes of the TFT 10 having the vertical structure. As such, risks of ion gas diffusing into the active section 21B from the second conductive part 21C can be reduced when the second conductive part 21C is polysilicon formed from silicide doped with high-concentration n-type impurities.

In the present embodiment, the thickness of the first conductive part 21C is greater than the thickness of the first conductive part 21A. Therefore, ion gas is prevented from diffusing toward the active section 21B when the second conductive part 21C is formed on the active section 21B. As such, working stability of the TFT 10 having the vertical structure is ensured.

It should be noted that, in the present embodiment, the thickness of the second conductive part 21C is greater than or equal to 50 nm and is less than or equal to 300 nm. Preferably, the thickness of the second conductive part 21C is 100 nm, 150 nm, or 200 nm.

Furthermore, in the present embodiment, a dopant concentration of an ion of the second conductive part 21C is less than a dopant concentration of an ion of the first conductive part 21A. It should be understood that, in the present embodiment, the second conductive part 21C having a relatively low dopant concentration of an ion is formed on the active section B, which is beneficial for reducing short-channel effects of the TFT, thereby optimizing performance of the TFT 10 having the vertical structure.

In the present embodiment, the TFT 10 having the vertical structure includes a buffer layer 13, the active layer 21, an insulating layer 22, a gate 23, an interlayer insulating layer 24, and a first metal layer which are stacked on the TFT 10 having the vertical structure. The first metal layer includes the drain 25B connected to the first conductive part 21A and the source 25A connected to the second conductive part 21C.

An orthographic projection of the gate 23 on a lateral wall 211 of the active layer 21 covers the active section 21B. Specifically, in the present embodiment, the orthographic projection of the gate 23 on the insulating substrate 11 overlaps a side of an orthographic projection of the active section 21B on the insulating substrate 11. Therefore, a current of the channel 210 of the TFT 10 having the vertical structure can be adjusted by the gate 23.

In the present embodiment, the TFT 10 having the vertical structure further includes a first through-hole 241 and a second through-hole 242 penetrating the interlayer insulating layer 24, the gate 23, and the insulating layer 22. The drain 25B is connected to the first conductive part 21A by the first through-hole 241. The source 25A is connected to the second conductive part 21C by the second through-hole 242. Moreover, the first conductive part 21A includes a first sub-conductive part 21A1 connected to the active section 21B and a second sub-conductive part 21A2 connected to the drain 25B. An orthographic projection of the first sub-conductive part 21A1 on the insulating substrate overlaps an orthographic projection of the second conductive part 21C on the insulating substrate. An orthographic projection of the sub-second conductive part 21A2 on the insulating substrate does not overlap the orthographic projection of the second conductive part 21C on the insulating substrate. That is, in the present embodiment, along a direction from the source 25A toward the drain 25B, a length of the first conductive part 21A is greater than a length of the second conductive part 21C. The first through-hole 241 is located on the second sub-conductive part 21A2, and the second through-hole 242 is located on the second conductive part 21C, which make the drain 25B and the first conductive part 21A easy to be connected. Compared with conventional TFTs, in the present embodiment, a distance between the source 25A and the drain 25B is increased. Thus, short-circuiting is prevented from occurring due to contact between the source 25A and the drain 25B, which is beneficial for improving a manufacturing yield rate of products.

In the present embodiment, the TFT 10 having the vertical structure further includes a light-shielding layer 12 disposed between the insulating substrate 11 and the buffer layer 13. An orthographic projection of the light-shielding layer 12 on the insulating substrate 11 at least covers an orthographic projection of the active section 21B on the insulating substrate 11. Light emitted toward the active section 21B can be blocked by the light-shielding layer 12. Therefore, a leakage current can be prevented from being increased due to photo-generated carriers caused by light irradiation. As such, working stability of the TFT 10 having the vertical structure can be ensured.

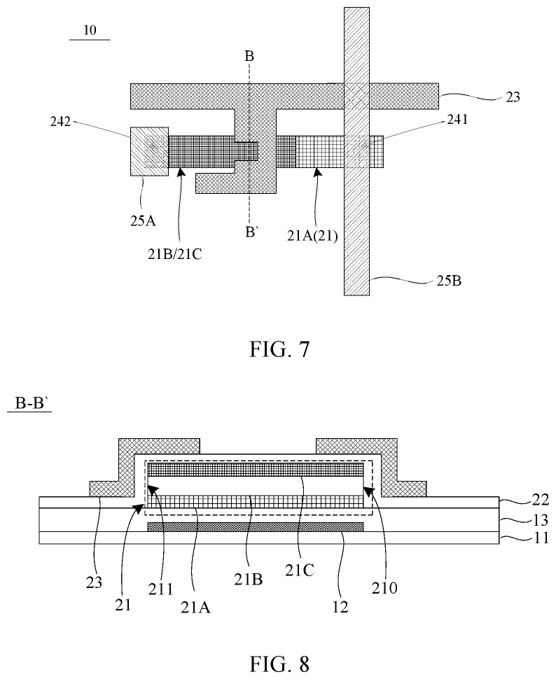

In another embodiment, please refer to FIG. 7 and FIG. 8. FIG. 7 is a second schematic top view showing a TFT having a vertical structure provided by an embodiment of the present disclosure. FIG. 8 is a structural schematic view showing a cross-section in FIG. 7 taken along a direction B-B′.

In the present embodiment, the TFT having the vertical structure has a similar structure to the TFT having the vertical structure of the above embodiments which can be referred to the above description and is not described here again. Differences therebetween are:

In the present embodiment, the orthographic projection of the gate 23 on the insulating substrate 11 overlaps two or multiple sides of the orthographic projection of the active section 21B on the insulating substrate 11. Compared with the above embodiments, in the present embodiment, the orthographic projection of the gate 23 on the insulating substrate 11 overlaps two or multiple sides of the orthographic projection of the active section 21B on the insulating substrate 11. Therefore, a width of the channel 210 can be controlled, and a current of the channel 210 of the TFT 10 having the vertical structure can be further adjusted.

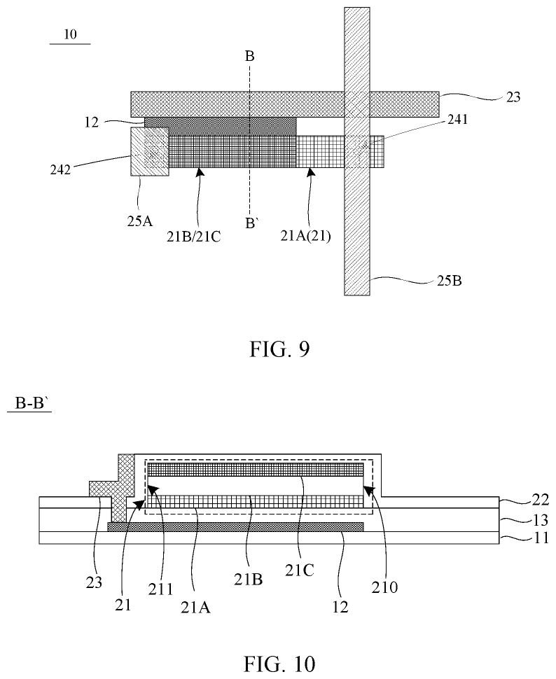

In another embodiment, please refer to FIG. 9 and FIG. 10. FIG. 9 is a third schematic top view showing a TFT having a vertical structure provided by an embodiment of the present disclosure. FIG. 10 is a structural schematic view showing a cross-section taken along a direction B-B′ in FIG. 9.

In the present embodiment, the TFT having the vertical structure has a similar structure to the TFT having the vertical structure of the above embodiments which can be referred to the above description and is not described here again. Differences therebetween are:

In the present embodiment, the orthographic projection of the gate 23 on the lateral wall 211 of the active layer 21 covers the active section 21B, and the gate 23 is connected to the light-shielding layer 12. It should be understood that the gate 23 is connected to the light-shielding layer 12. As such, when TFT 10 having the vertical structure works, the light-shielding layer 12 and the gate 23 have a same electric potential. The gate 23 and the light-shielding layer 12 together apply an electric field to the active section 21B, thereby increasing a capability of the TFT 10 having the vertical structure to control the channel 210.

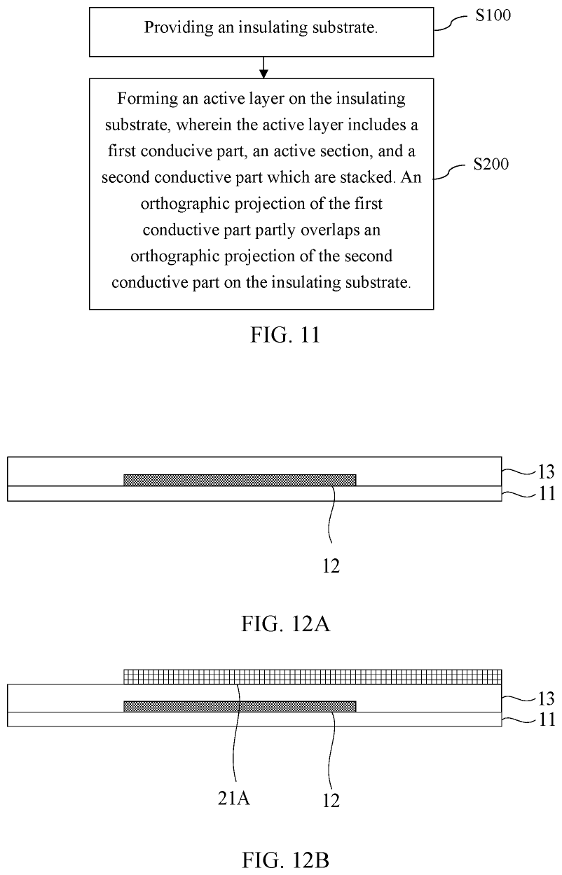

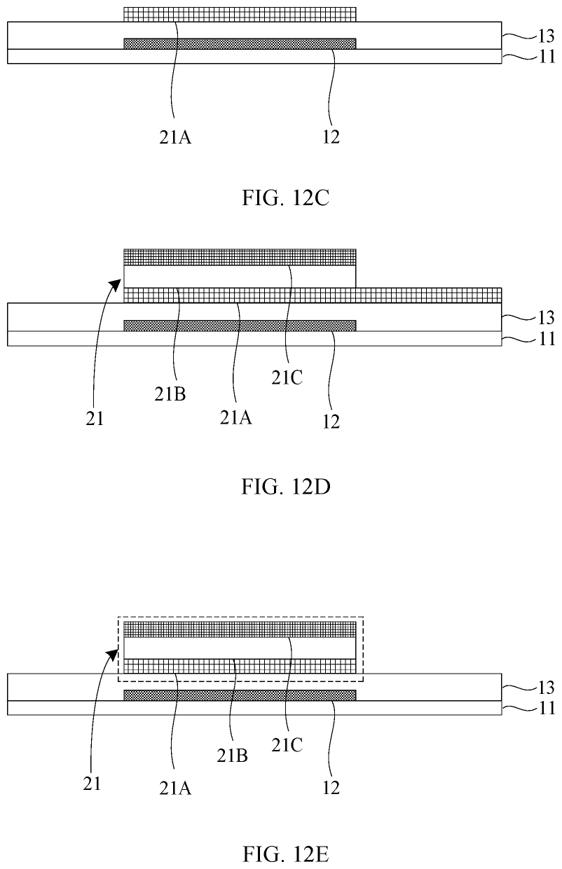

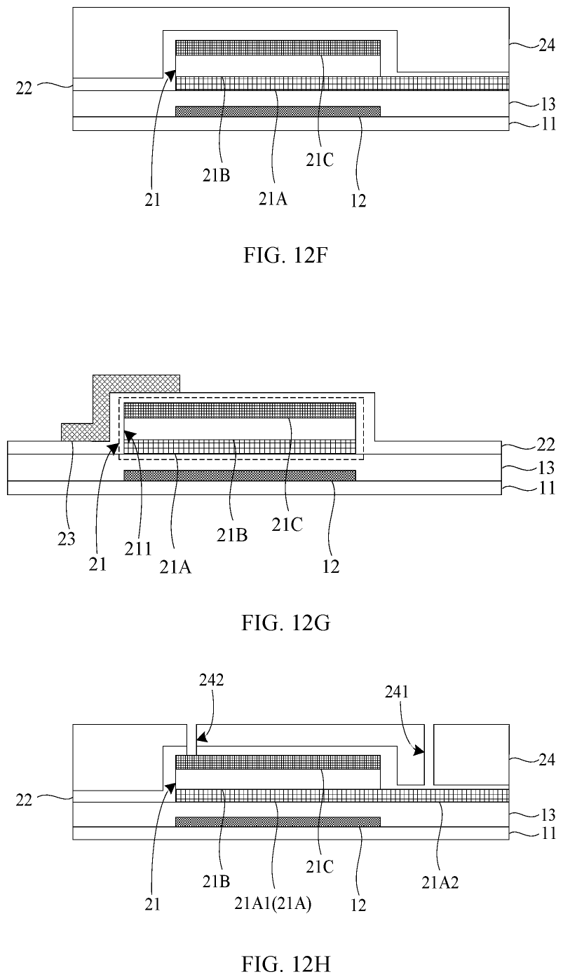

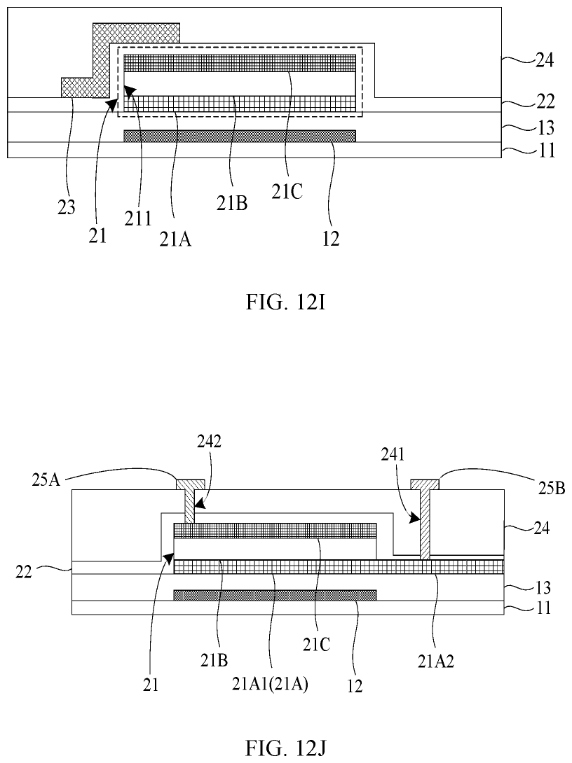

An embodiment of the present disclosure provides a method of manufacturing a TFT 10 having a vertical structure. Please refer to FIG. 11 and FIGS. 12A to 12J. FIG. 11 is a flowchart showing a manufacturing method of a TFT having a vertical structure provided by an embodiment of the present disclosure. FIGS. 12A to 12J are manufacturing flowcharts showing structures of the TFT having the vertical structure in FIG. 11.

In the present embodiment, the method of manufacturing the TFT 10 having the vertical structure includes following steps:

Step S100, providing an insulating substrate 11.

When the insulating substrate 11 is a rigid substrate, material of the insulating substrate 11 may be metal or glass. When the insulating substrate 11 is a flexible substrate, material of the insulating substrate 11 may be at least one of an acrylic resin, a methacrylic resin, polyisoprene, a vinyl resin, an epoxy resin, a polyurethane resin, a cellulose resin, a silicone resin, a polyimide resin, or a polyamide resin.

Step S200, forming an active layer 21 on the insulating substrate 11, wherein the active layer 21 includes a first conductive part 21A, an active section 21B, and a second conductive part 21 which are stacked. An orthographic projection of the first conductive part 21A partly overlaps an orthographic projection of the second conductive part 21C on the insulating substrate 11.

It should be noted that, in the present embodiment, the active section 21B and the second conductive part 21C have a same shape. Before the step S200, the method of manufacturing the TFT 10 having the vertical structure includes following steps:

Step S110, sequentially forming a light-shielding layer 12 and a buffer layer 13 on the insulating substrate 11, as shown in FIG. 12. A thickness of the light-shielding layer 12 is greater than or equal to 10 nm and is less than or equal to 300 nm. Material of the light-shielding layer 12 includes, but is not limited to, metal. The metal includes, but is not limited to, an alloy including one or more of Mo, Ti, and Ni. Material of the buffer layer 13 includes, but is not limited to, a single layer of Si₃N₄, a single layer of SiO₂, a single layer of SiONₓ, or two layers of the above layers.

Specifically, in the present embodiment, the step S200 includes following steps:

Step 201, forming a first amorphous silicon (a-Si) layer on the buffer layer 13, and crystallizating the first a-SI layer to form a first polysilicon thin film. Specifically, a layer of a-Si material is deposited on the buffer layer 13 to form the first a-Si layer. A thickness of the first a-Si layer is greater than or equal to 10 nm and is less than or equal to 100 nm. Preferably, the thickness of the first a-Si layer is 35 nm, 45 nm, or 55 nm. Then, an excimer laser annealing (LEA) process is performed on the first a-SI layer to form the first polysilicon thin film.

Step S202, patterning the first polysilicon thin film to form a first polysilicon pattern. Specifically, the first polysilicon thin film is patterned in lithography and etching processes with a mask and a positive photoresist, thereby forming the first polysilicon pattern on the buffer layer 13.

Step S203, injecting ions into the first polysilicon pattern to form the first conductive part 21A, as shown in FIG. 12B and FIG. 12C. The ions injected into the first polysilicon pattern are boron ions or phosphorus ions.

Step S204, forming a second a-Si layer on the first conductive part 21A, and crystallizating the second a-SI layer to form a second polysilicon thin film. Specifically, a layer of a-Si material is deposited on the first conductive part 21A to form the second a-Si layer. A thickness of the second a-Si layer is greater than or equal to 10 nm and is less than or equal to 100 nm. Preferably, the thickness of the second a-Si layer is 20 nm, 30 nm, or 40 nm. Then, an LEA process is performed on the second a-SI layer to form the second polysilicon thin film.

Step S205, patterning the second polysilicon thin film to form the active section 21B. Specifically, the second polysilicon thin film is patterned in lithography and etching processes with a mask and a positive photoresist, thereby forming the active section 21B on the first conductive part 21A. An orthographic projection of the active section 21B on the insulating substrate 11 partly overlaps an orthographic projection of the first conductive part 21A on the insulating substrate 11.

Step S206, forming a third a-Si layer on the active section 21B, and crystallizating the third a-SI layer to form third second polysilicon thin film. Specifically, a layer of a-Si material is deposited on the active section 21B to form the third a-Si layer. A thickness of the third a-Si layer is greater than or equal to 50 nm and is less than or equal to 300 nm. Preferably, the thickness of the third α-Si layer is 100 nm, 150 nm, or 200 nm. Then, an LEA process is performed on the third a-SI layer to form the third polysilicon thin film.

Step S207, patterning the third polysilicon thin film to form a second polysilicon pattern. Specifically, the third polysilicon thin film is patterned in lithography and etching processes with a mask and a positive photoresist, thereby forming the second polysilicon pattern on the buffer layer 13.

Step S208, injecting ions into the second polysilicon pattern to form the second conductive part 21C. The second conductive part 21C and the active section 21B have a same shape. An orthographic projection of the second conductive part 21C on the insulating substrate 11 partly overlaps an orthographic projection of the first conductive part 21A on the insulating substrate 11. Preferably, in the present embodiment, the orthographic projection of the first conductive part 21A on the insulating substrate 11 overlaps the orthographic projection of the second conductive part 21C on the insulating substrate 11, as shown in FIG. 12D and FIG. 12E.

It should be noted that, in the present embodiment, the ions injected into the second polysilicon pattern are boron ions or phosphorus ions. Furthermore, a dopant concentration of ions of the second conductive part 21C is less than a dopant concentration of ions of the first conductive part 21a. It should be understood that, in the present embodiment, the second conductive part 21C having a relatively low dopant concentration of ions is formed on the active section 21B. Therefore, dopant ions of the second conductive part 21C are not easy to diffuse into the active section 21B, which is beneficial for reducing short-channel effects of the TFT, thereby optimizing performance of the TFT 10 having the vertical structure.

Moreover, in the present embodiment, the thickness of the third a-Si layer is greater than or equal to 50 nm and is less than or equal to 300 nm, and thickness of the first a-Si layer is greater than or equal to 10 nm and is less than or equal to 100 nm. Therefore, the thickness of the second conductive part 21C is greater than the thickness of the first conductive part 21A. As such, plasma gas may be prevented from diffusing toward the active section 21B when the active section 21B is formed on the second conductive part 21C, thereby ensuring working stability of the TFT 10 having the vertical structure.

Furthermore, it should be understood that, in the present embodiment, the active layer 21 includes the first conductive part 21A, the active section 21B, and the second conductive section 21C which are stacked. The channel 210 of the TFT 10 having the vertical structure is disposed between the first conductive part 21A and the second conductive part 21C. That is, in the present embodiment, a length of the channel 210 of the TFT 10 having the vertical structure can be determined by a thickness of the active section 21B. Therefore, although the thickness of the active section 21B is limited because of exposure apparatuses, the thickness of the active section 21B may be controlled. As such, the length of the channel 210 may be controlled independently of exposure apparatuses, and a short channel of the TFT can be realized.

In conventional manufacturing processes of TFTs, contamination ions may diffuse from the insulating substrate toward the active layer 21, destroying stability of the TFTs. In the present embodiment, the active section 21B and the second conductive part 21C have the same shape. The orthographic projection of the first conductive part 21A on the insulating substrate 11 partly overlaps the orthographic projection of the second conductive part 21C on the insulating substrate 11. Therefore, contamination ions can be prevented from entering the active section 21B from the insulating substrate 11 during manufacturing processes of the TFT, thereby improving stability of the TFT.

In the present embodiment, the method of manufacturing the TFT 10 having the vertical structure further includes following steps:

Step S300, forming an insulating layer 22 on a side of the active layer 21 away from the insulating substrate 11, as shown in FIGS. 12F and 12G. The insulating layer 22 covers the active layer 21, thereby blocking moisture and oxygen from entering the active layer 21 and realizing an insulating function. A thickness of the insulating layer 22 is greater than or equal to 30 nm and is less than or equal to 200 nm. Material of the insulating layer 22 includes, but is not limited to, a single layer of Si₃N₄, a single layer of SiO₂, a single layer of SiONₓ, or two layers of the above layers.

Step S400, forming a gate 23 on a side of the insulating layer 22 away from the active layer 21. An orthographic projection of the gate 23 on a lateral wall 211 of the active layer 21 covers the active section 21B. Specifically, in the present embodiment, the orthographic projection of the gate 23 on the insulating substrate 11 overlaps a side of the orthographic projection of the active section 21B on the insulating substrate 11. Therefore, the gate 23 can control a current of the channel 210 of the TFT having the vertical structure, as shown in FIGS. 12F and 12E.

A thickness of the gate 23 is greater than or equal to 0.1 μm and is less than or equal to 1 μm. Material of the gate 23 is metal. The metal includes, but is not limited to, at least one of Mo, Al, Pt, Pd, Ag, Mg, Au, Ni, Nd, Ir, Cr, Ca, Ti, Ta, or W. The present embodiment does not limit the material of the gate 23.

Step S500, forming an interlayer insulating layer 24 on a side of the gate 23 away from the gate 23. The interlayer insulating layer 23 covers the gate 23, thereby blocking moisture and oxygen from entering the gate 23 and realizing an insulating function. Material of the interlayer insulating layer 24 includes, but is not limited to, a single layer of Si₃N₄, a single layer of SiO₂, a single layer of SiONₓ, or two layers of the above layers.

Step S600, forming a first through-hole 241 and a second through-hole 242 on the gate 23 and the interlayer insulating layer 24 by a mask process. The first through-hole 241 penetrates the gate 23 and the interlayer insulating layer 24 and exposes part of the first conductive part 24A, and the second through-hole 242 penetrates the gate 23 and the interlayer insulating layer 24 and exposes part of the second conductive part 21C, as shown in FIG. 12H and FIG. 12I.

Step S700, forming a source 25A and a drain 25B on a side of the interlayer insulating layer 24 away from the gate 23. The drain 25B is connected to the first conductive part 21A by the first through-hole 241. The drain 25A is connected to the second conductive part 21C by the second through-hole 242.

The first conductive part 24A includes a first sub-conductive part 21A1 connected to the active section 21B and a second sub-conductive part 21A2 connected to the drain 25B. An orthographic projection of the first sub-conductive part 21A1 on the insulating substrate overlaps an orthographic projection of the second conductive part 21C on the insulating substrate. An orthographic projection of the second sub-conductive part 21A2 on the insulating substrate does not overlap the orthographic projection of the second conductive part 21C on the insulating substrate. The first through-hole 241 is located on the second sub-conductive part 21A2, as shown in FIG. 12J.

Material of the source 25A and material of the drain 25B are metal. The metal includes, but is not limited to, but is not limited to, at least one of Mo, Al, Pt, Pd, Ag, Mg, Au, Ni, Nd, Ir, Cr, Ca, Ti, Ta, or W. The present embodiment does not limit the material of the source 25A and the material of the drain 25B.

It should be noted that, in the present embodiment, FIGS. 12A, 12C, 12E, 12G, and 12I are cross-sectional schematic views in FIG. 4 taken along direction B-B′, and FIGS. 12B, 12D, 12F, 12H, and 12J are cross-sectional schematic views in FIG. 4 taken along direction A-A′.

It should be noted that, in another embodiment, the step S200 may further include following steps:

Step S201, forming a first conductive part 21A on the insulating layer 13A, wherein the first conductive part 21A is an a-Si layer doped with high-concentration n-type impurities.

Step 202, forming an a-Si layer on the first conductive part 21A, and crystallizating the a-SI layer to form a polysilicon thin film. Specifically, a layer of a-Si material is deposited on the first conductive part 21A to form the a-Si layer. A thickness of the a-Si layer is greater than or equal to 10 nm and is less than or equal to 100 nm. Preferably, the thickness of the a-Si layer is 20 nm, 30 nm, or 40 nm. Then, an LEA process is performed on the a-SI layer to form the polysilicon thin film.

Step S203, patterning the polysilicon thin film to form an active section 21B. Specifically, the polysilicon thin film is patterned in lithography and etching processes with a mask and a positive photoresist, thereby forming the active section 21B on the first conductive part 21A. An orthographic projection of the active section 21B on the insulating substrate 11 partly overlaps an orthographic projection of the first conductive part 21A on the insulating substrate 11.

Step S204, forming a second conductive part 21C on the active section 21B. The second conductive part 21C is an a-Si layer doped with high-concentration n-type impurities. The second conductive part 21C and the active section 21B have a same shape. An orthographic projection of the second conductive part 21C on the insulating substrate 11 partly overlaps the orthographic projection of the first conductive part 21A on the insulating substrate 11. Preferably, in the present embodiment, the orthographic projection of the first conductive part 21A on the insulating substrate 11 covers the orthographic projection of the second conductive part 21C on the insulating substrate 11.

It should be understood that, in the present embodiment, both the first conductive part 21A and the second conductive part 21C are the a-Si layer doped with high-concentration n-type impurities. Therefore, it is not necessary to additionally inject ions during manufacturing processes of the TFT 10 having the vertical structure. As such, risks of ion gas diffusing into the active section 21B from the second conductive part 21C can be reduced when the second conductive part 21C is polysilicon formed from silicide doped with high-concentration n-type impurities.

An embodiment of the present disclosure provides an electronic device. The electronic device includes any one of the TFT having the vertical structure of any one of the above embodiments.

It should be understood that the TFT having the vertical structure has been described in detail in the above embodiments and is not described here again.

The electronic device may be a display screen of a smartphone, a tablet, a notebook, a smart bracelet, a smartwatch, smart glasses, a smart helmet, a desktop, a smart television, or a digital camera. The electronic device can even be applied to electronic devices having flexible display screens.

In the above embodiments, the focus of each embodiment is different, and for a part that is not detailed in an embodiment, reference may be made to related descriptions of other embodiments.

The TFT having the vertical structure and the electronic device have been described in detail with embodiments provided by the present disclosure which illustrate principles and implementations thereof. However, the description of the above embodiments is only for helping to understand the technical solution of the present disclosure and core ideas thereof, and it is understood by those skilled in the art that many changes and modifications to the described embodiment can be carried out without departing from the scope and the spirit of the disclosure that is intended to be limited only by the appended claims.

What is claimed is:

1. A thin-film transistor (TFT) having a vertical structure, comprising:
an insulating substrate;
an active layer disposed on the insulating substrate, wherein the active layer comprises a first conductive part, an active section, and a second conductive part which are stacked;
wherein an orthographic projection of the first conductive part on the insulating substrate partly overlaps an orthographic projection of the second conductive part on the insulating substrate.

2. The TFT having the vertical structure of claim 1, wherein a thickness of the second conductive part is greater than a thickness of the first conductive part.

3. The TFT having the vertical structure of claim 2, wherein the thickness of the second conductive part is two times greater than the thickness of the first conductive part.

4. The TFT having the vertical structure of claim 2, wherein in a direction perpendicular to the insulating substrate, the thickness of the second conductive part is greater than or equal to 50 nm and is less than or equal to 300 μm, and the thickness of the first conductive part is greater than or equal to 10 nm and is less than or equal to 100 μm.

5. The TFT having the vertical structure of claim 1, wherein the active layer comprises a first active layer, a second active layer, and a third active layer which are stacked and disposed on the insulating substrate;
wherein the active layer comprises the first conductive part doped with an ion, and the third active layer comprises the second conductive part doped with an ion.

6. The TFT having the vertical structure of claim 1, wherein the active layer section and the second conductive part have a same shape.

7. The TFT having the vertical structure of claim 1, wherein a dopant concentration of the ion of the second conductive part is less than a dopant concentration of the ion of the first conductive part.

8. The TFT having the vertical structure of claim 1, comprising a gate disposed on a lateral wall of the active layer, and an orthographic projection of the gate on the lateral wall of the active layer covers the active section.

9. The TFT having the vertical structure of claim 8, wherein the orthographic projection of the gate on the insulating substrate overlaps a side of an orthographic projection of the active section on the insulating substrate.

10. The TFT having the vertical structure of claim 8, wherein the orthographic projection of the gate on the insulating substrate overlaps two sides or multiple sides of an orthographic projection of the active section on the insulating substrate.

11. The TFT having the vertical structure of claim 8, comprising:
a light-shielding layer disposed between the insulating substrate and the active layer, wherein an orthographic projection of the light-shielding layer on the insulating substrate at least covers an orthographic projection of the active section on the insulating substrate, and the gate is connected to the light-shielding layer.

12. The TFT having the vertical structure of claim 1, wherein a thickness of the active section is greater than or equal to 0.1 μm and is less than or equal to 1 μm.

13. The TFT having the vertical structure of claim 1, comprising a first metal layer disposed on a side of the active layer away from the insulating substrate, wherein the first metal layer is connected to the first conductive layer;
wherein the first conductive part comprises a first sub-conductive part connected to the active section and a second sub-conductive part connected to the first metal layer, an orthographic projection of the first sub-conductive part on the insulating substrate overlaps an orthographic projection of the second conductive part on the insulating substrate, and an orthographic projection of the second sub-conductive part on the insulating substrate does not overlap the orthographic projection of the second sub-conductive part on the insulating substrate.

14. An electronic device, comprising the TFT having the vertical structure of claim 1.
